(19) United States
(12) Patent Application Publication
(10) Pub. No.: US 2011/0037367 A1
(43) Pub. Date: Feb. 17, 2011

(54) SOLID-STATE LIGHT BULB HAVING ION WIND FAN AND INTERNAL HEAT SINKS

(75) Inventors: Wei-Min Jeff WANG, Palo Alto, CA (US); Daniel Jon Schlitz, Northbrook, IL (US); Ashwini Choudhary, San Jose, CA (US); Scott L. Gooch, San Carlos, CA (US)

Correspondence Address: PILLSBURY WINTHROP SHAW PITTMAN LLP, P.O. BOX 10500, MCLEAN, VA, 22102, US

(73) Assignee: Ventiva, Inc., Santa Clara, CA (US)

(21) Appl. No.: 12/818,921

(22) Filed: Jun. 18, 2010

Related U.S. Application Data
(60) Provisional application No. 61/297,146, filed on Jan. 21, 2010.
(60) Provisional application No. 61/233,112, filed on Aug. 11, 2009.

(51) Int. Cl. H01J 61/52; H05K 7/20

(52) U.S. Cl. 313/46; 361/697

(57) ABSTRACT

An ion wind fan can be incorporated into a solid-state lighting device to thermally manage the lighting device. In one embodiment, the lighting device includes a bulb body having air intake and exhaust openings, and an ion wind fan to generate airflow between the openings. The lighting device can further include an upstream heat sink disposed upstream of the ion wind fan with respect to the airflow, the upstream heat sink having a shape that provides no direct line of sight from the air intake openings to the ion wind fan.

### CROSS-REFERENCE TO RELATED APPLICATION

This Application is related to and claims the priority benefit of U.S. Provisional Patent Application No. 61/297,146 entitled “LED Lamp Cooling Using Ion Wind Fan,” filed Jan. 21, 2010 and this Application is further related to and claims the priority benefit of U.S. Provisional Patent Application No. 61/233,112 entitled “Mitigating Ozone in a Device Having an EHD Solid State Fan,” filed on Aug. 11, 2009.

### FIELD OF THE INVENTION

Embodiments of the present invention are directed to thermal management for solid state lighting, and in particular to a solid-state light bulb containing an ion wind fan.

### BACKGROUND

LEDs and other solid-state light devices convert more of their energy usage to heat than to light. Thus, thermal management of solid-state lighting is necessary to avoid overheating the solid-state lighting devices.

Most LED manufacturers manage heat in LED lights by providing an external heat sink that doubles as the body of the LED bulb. The LEDs are then thermally coupled to the heat sink, usually in a highly inefficient manner and at some distance from the heat sink. Heat sinks are a common passive tool used for thermal management. Heat sinks use conduction and convection to dissipate heat and thermally manage the heat-producing component.

To increase the heat dissipation of a heat sink, a conventional rotary fan or blower fan has been used to move air across the surface of the heat sink, referred to generally as forced convection. One way to integrate a traditional fan into an LED bulb is described in U.S. Pat. No. 7,144,135 to Martin, et al. entitled “TED Lamp Heat Sink.” Conventional fans have many disadvantages when used in consumer electronics products, such as noise, weight, size, and reliability caused by the failure of moving parts and bearings.

A solid-state fan using ionic wind to move air addresses the disadvantages of conventional fans. However, integrating an ion wind fan into an LED bulb poses many challenges.

### BRIEF DESCRIPTION OF THE DRAWINGS

FIG. 1 is a block diagram illustrating an ion wind fan implemented as part of thermal management of an electronic device;

FIG. 2A is a perspective view of one embodiment of an ion wind fan;

FIG. 2B is a widthwise cross-sectional view of the embodiment of the ion wind fan of FIG. 2A;

FIG. 3 is a perspective lengthwise cross-sectional view of a prior art LED light bulb;

FIG. 4 is a perspective lengthwise cross-sectional view of a portion of an LED light bulb according to one embodiment of the present invention;

FIG. 5 is a perspective bottom view of a heat spreader/heat sink module according to one embodiment of the present invention;

FIG. 6 is a perspective widthwise cross-sectional view of an LED light bulb according to one embodiment of the present invention;

FIG. 7 is a perspective bottom view of a heat spreader/heat sink module according to another embodiment of the present invention;

FIG. 8 is a bottom plan view of a heat spreader/heat sink/ion wind fan module according to one embodiment of the present invention;

FIG. 9 is a perspective bottom view of a heat spreader/heat sink/ion wind fan module according to one embodiment of the present invention;

FIG. 10 is a perspective lengthwise cross-sectional view of an LED light bulb according to another embodiment of the present invention;

FIG. 11 is a perspective widthwise cross-sectional view of an LED light bulb according to one embodiment of the present invention;

FIG. 12A is a top plan view of a heat sink according to another embodiment of the present invention;

FIG. 12B is a top plan view of a heat sink according to yet another embodiment of the present invention; and

FIG. 13 is a perspective view a heat pipe/heat sink module according to one embodiment of the present invention.

### DETAILED DESCRIPTION

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not necessarily be so limited; rather the principles thereof can be extended to other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

Ion wind or corona wind generally refers to the gas flow that is established between two electrodes, one sharp and the other blunt, when a high voltage is applied between the electrodes. The air is partially ionized in the region of high electric field near the sharp electrode. The ions that are attracted to the more distant blunt electrode collide with neutral (uncharged) molecules en route to the collector electrode and create a pumping action resulting in air movement. The high voltage sharp electrode is generally referred to as the emitter electrode or corona electrode, and the grounded blunt electrode is generally referred to as the counter electrode or collector electrode.

The general concept of ion wind—also sometimes referred to as ionic wind and corona wind even though these concepts are not entirely synonymous—has been known for some time. For example, U.S. Pat. No. 4,210,847 to Shannon, et al., dated Jul. 1, 1980, titled “Electric Wind Generator” describes a corona wind device using a needle as the sharp corona electrode and a mesh screen as the blunt collector electrode. The concept of ion wind has been implemented in relatively large-scale air filtration devices, such as the Sharper Image Ionic Breeze.

### Example Ion Wind Fan Thermal Management Solution

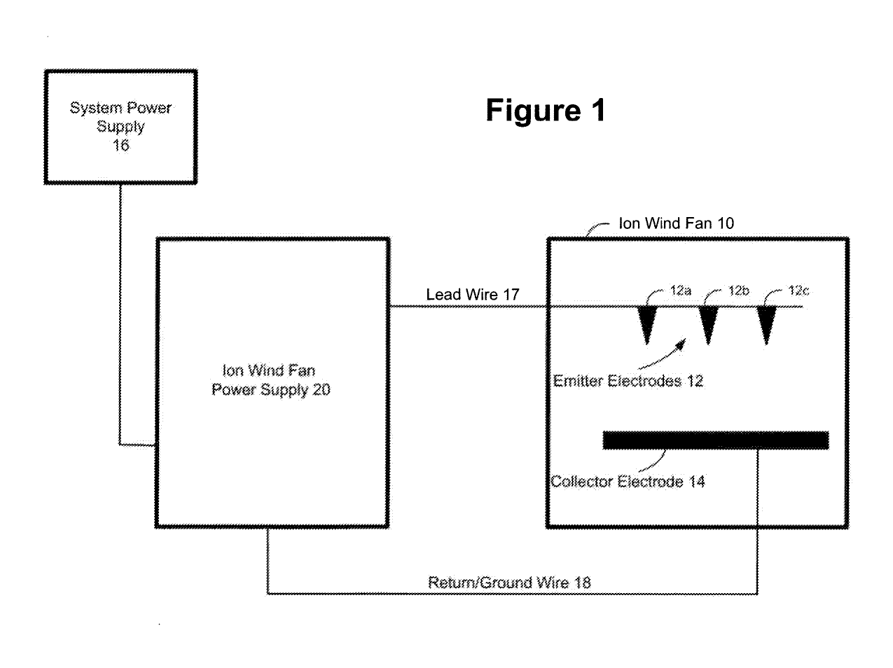

FIG. 1 illustrates an ion wind fan 10 used as part of a thermal management solution for an electronic device. As used in this Application, the descriptive term “ion wind fan,” is used to refer to any electro-aerodynamic pump, EHD pump, EHD thruster, corona wind device, ionic wind device, or any other such device used to move air or other gas. The term “fan” refers to any device that move air or some other gas. The term ion wind fan is meant to distinguish the fan from conventional rotary and blower fans. However, any type of ionic gas movement can be used in an ion wind fan, including, but not limited to corona discharge, dielectric barrier discharge, or any other ion generating technique.

An electronic device may need thermal management for an integrated circuit—such as a chip or a processor—that produces heat, or some other heat source, such as a light emitting diode (LED). Some example systems that can use an ion wind fan for thermal management include computers, laptops, gaming devices, projectors, television sets, set-top boxes, servers, NAS devices, memory devices, LED lighting devices, LED display devices, smart-phones, music players and other mobile devices, and generally any device having a heat source requiring thermal management.

The electronic device can have a system power supply 16 or can receive power directly from the mains AC via a wall outlet, Edison socket, or other outlet type. For example, in the case of a laptop computer, the laptop will have a system power supply such as a battery that provides electric power to the electronic components of the laptop. In the case of a wall-plug device such as a gaming device, television set, or LED lighting solution (lamp or bulb), the system power supply 16 will receive the 110V mains AC (in the U.S.A, 220V in the EU) current from an electrical outlet or socket.

The system power supply 16 for such a plug or screw-in device will also convert the mains AC into the appropriate voltage and type of current needed by the device (e.g., 20-50V DC for an LED lamp). While the system power supply 16 is shown as separate from the IWFPS 20, in some embodiments, one power supply can provide the appropriate voltage to both an ion wind fan 10 and other components of the electronic device. For example, a single driver can be design to drive the LEDs of and LED lamp and an ion wind fan included in the LED lamp.

The electronic device also includes a heat source (not shown), and may also include a passive thermal management element, such as a heat sink (also not shown). To assist in heat transfer, an ion wind fan 10 is provided in the system to help move air across the surface of the heat source or the heat sink, or just to generally circulate air (or some other gas) inside the device. In prior art systems, conventional rotary fans with rotating fan blades have been used for this purpose.

As discussed above, the ion wind fan 10 operates by creating a high electric field around one or more emitter electrodes 12 resulting in the generation of ions, which are then attracted to a collector electrode 14. In FIG. 1, the emitter electrodes 12 are represented as triangles as an illustration that they are generally “sharp” electrodes. However, in a real-world ion wind fan 10, the emitter electrodes 12 can be implemented as wires, shims, blades, pins, and numerous other geometries. Furthermore, while the ion wind fan 10 in FIG. 1 has three emitter electrodes (12a, 12b, 12c), the various embodiments of the present invention described herein can be implemented in conjunction with ion wind fans having any number of emitter electrodes 12.

Similarly, the collector electrode 14 is shown simply as a plate in FIG. 1. However, a real-world collector electrode 14 can have various shapes and will generally include openings to allow the passage of air. The collector electrode 14 can also be implemented as multiple collector electrodes (e.g., rods, washers) held at substantially the same potential. Since the specific emitter 12 and collector 14 geometries are not germane to the present invention, they are illustrated as triangles and plates for simplicity and ease of understanding. Furthermore, in a real world ion wind fan 10, the emitter electrodes 12 and the collector electrode 14 would be disposed on a dielectric chassis—sometimes referred to as an isolator element—that has also been omitted from FIG. 1 for simplicity and ease of understanding.

To create the high electric field necessary for ion generation, the ion wind fan 10 is connected to an ion wind power supply 20. The ion wind power supply 20 is a high-voltage power supply that can apply a high voltage potential across the emitter electrodes 12 and the collector electrode 14. The ion wind fan power supply 20 (hereinafter sometimes referred to as “IWFPS”) is electrically coupled to and receives electrical power from the system power supply 16. Usually for electronic devices, the system power supply 16 provides low-voltage direct current (DC) power. For example, a laptop computer system power supply would likely output approximately 5-12V DC, while the power supply for an LED light fixture would likely output approximately 20-70V DC.

The high voltage DC generated by the IWFPS 20 is then electrically coupled to the emitter electrodes 12 of the ion wind fan 10 via a lead wire 17. The collector electrode 14 is connected back to the IWFPS 20 via return/ground wire 18, to ground the collector electrode 14 thereby creating a high voltage potential across the emitters 12 and the collector 14 electrodes. The return wire 18 can be connected to a system, local, or absolute high-voltage ground using conventional techniques.

While the system shown in and described with reference to FIG. 1 uses a positive DC voltage to generate ions, ion wind can be created using AC voltage, or by connecting the emitters 12 to the negative terminal of the IWFPS 20 resulting in a “negative” corona wind. Embodiments of the present invention are not limited to positive DC voltage ion wind. Furthermore, while the IWFPS 20 is shown to receive power from a system power supply 30, in other embodiment, the IWFPS 20 can receive power directly from an outlet.

The IWFPS 20 may include other components. Furthermore, in some embodiments, some of the components listed above may be omitted or replaced by similar or equivalent circuits. For example, the IWFPS 20 is described only as an example. Many different kinds and types of power supplies can be used as the IWFPS 20, including power supplies that do not have a transformers or other components shown in FIG. 1. The components described need not be physically separate, and may be combined on a single printed circuit board (PCB).

As described partially above, ion wind is generated by the ion wind fan 10 by applying a high voltage potential across the emitter 12 and collector 14 electrodes. This creates a strong electric field around the emitter electrodes 12, strong enough to ionize the air in the vicinity of the emitter electrodes 12, in effect creating a plasma region. The ions are attracted to collector electrode 12, and as they move in air gap along the electric field lines, the ions bump into neutral air molecules, creating airflow. On a real world collector electrode 14, air passage openings (not shown) allow the airflow to pass through the collector 14 thus creating an ion wind fan.

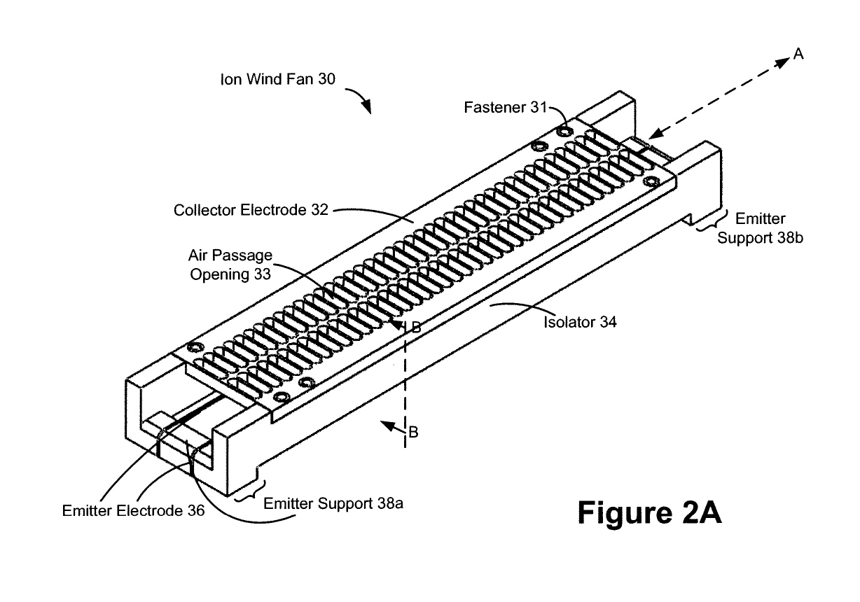

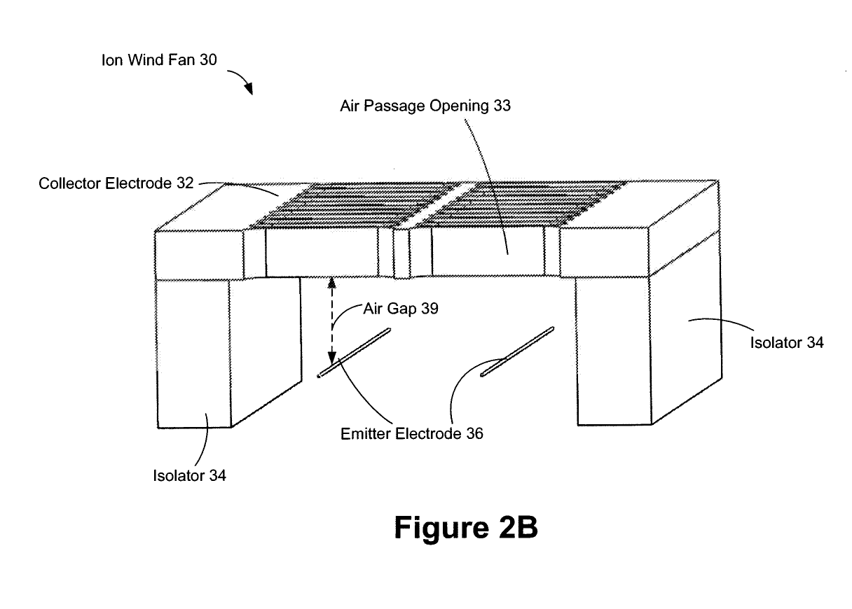

An example of such an ion wind fan is now described with reference to FIGS. 2A and 2B. FIG. 2A is a perspective view of an example ion wind fan 30. The ion wind fan 30 includes a collector electrode 32 having air passage openings 33 to allow airflow. This example ion wind fan 30 has two emitter electrodes 36 implemented as wires, thus implementing what is sometimes referred to as a “wire-to-plane” configuration.

The collector electrode 32 and the emitter electrodes 36 are both supported by an isolator 34. The isolator is made of a dielectric material, such as plastic. The “isolator” component is thusly named as it functions to electrically isolate the emitter electrodes 36 from the collector electrode 32, and to physically support these electrodes and establish the spatial relationship between the electrodes. The isolator 34 can be made from one integral piece—as shown in FIG. 2A—or it can be made of multiple parts and pieces.

In the embodiment shown in FIG. 2A, the collector electrode is attached to the isolator using a fastener 31. The fastener 31 in FIG. 2 is a stake, but any other attachment method can be used, including but not limited to screws, hooks, glue, and so on. Similarly, the particular method of attachment of the emitter electrodes 36 is not essential to the embodiments of the present invention. The emitter electrodes 36 can be glued, staked, screwed, tied, held by friction, or attached in any other way to the isolator 34.

The ion wind fan 30—in the embodiment shown in FIG. 2A—is substantially rectangular in top view. The longitudinal axis of the ion wind fan 30 is denoted with the dotted arrow labeled “A.” The ion wind fan 30 has two ends opposite each other along the longitudinal axis. The emitter electrodes 36 are suspended between the two ends of the ion wind fan 30.

FIG. 2B further illustrates the example ion wind fan 30 shown in FIG. 2A. FIG. 2B is a perspective cross sectional view of the ion wind fan 30 along the line B-B shown in FIG. 2A. The emitter electrodes 36 are suspended in air, and held a substantially constant air gap 39 distance away from the collector electrode 32.

Though wire sag and other emitter irregularities will create some variance, in one embodiment the air gap 39 between the emitter electrodes 36 and the bottom plane of the collector electrode 32 is substantially constant (within a 5% variation). In other embodiments, the air gap 39 can be more variable. The size of the air gap 39 is dependent on the spatial relationship between the electrodes.

The ion wind fan 30 described with reference to FIGS. 2A-B above is just one of many possible types and geometries of ion wind fan that can be used. Various different types of electrodes and isolator configurations are possible. For example, the ion wind fan need not be rectangular in top view; it could be square, circular or oval, cylindrical, and many other shapes. The embodiments of the present invention are not limited to any specific ion wind fan or ionic air pump, and the ion wind fan 30 was described above merely as an example of one possible ion wind fan that can be used.

### Solid State Light Bulbs

While there are various solid-state light devices and semiconductor devices capable of emitting light, such as light-emitting diodes (LEDs), LED arrays, Vertical-cavity surface-emitting lasers (VCSELs), VCSEL arrays, and photon recycling devices among others, the embodiments of the present invention will be described largely with reference to an LED light bulb, as LEDs are currently the most popular device for solid state lighting. However, the embodiments described are not limited to LEDs, and any other solid state or semiconductor light device can be substituted for LEDs in the embodiments described herein.

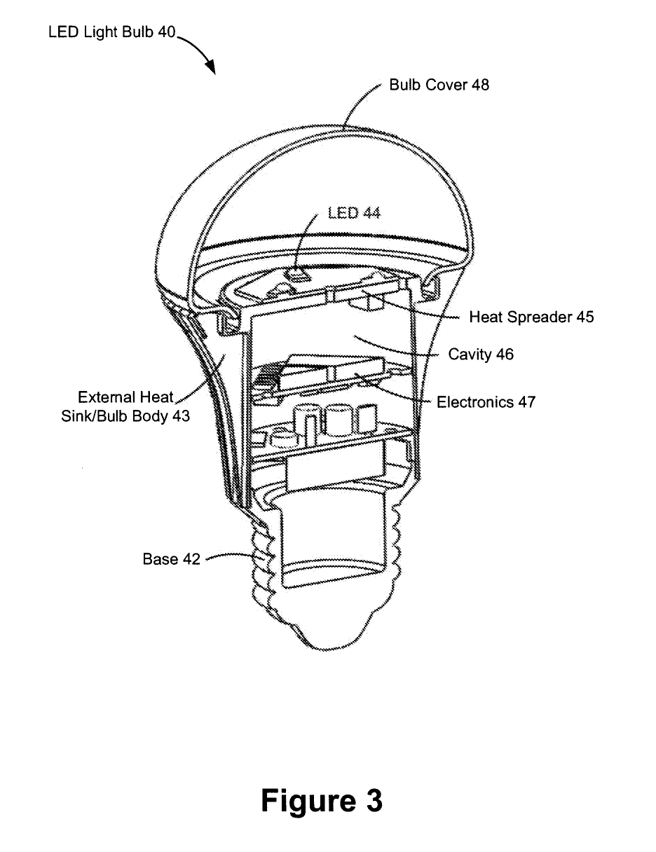

FIG. 3 is a cross-sectional view of an example prior art LED light bulb 40. The LED light bulb 40 has the approximate form factor of an A-series bulb. The A-series bulb, also sometimes referred to as the A-lamp, is the most common bulb shape for incandescent light bulbs. A-bulbs in the United States range from the A-15 to the A-23, with the A-19 being the most commonly seen (the numerals indicate maximum bulb diameter in ⅛^{th} inches; A-19 is 19/8 inches in diameter). In Europe, the A-55 bulb is similar in proportions to the A-19 bulb.

The LED light bulb 40 is representative of the currently avaible LED bulbs, such as the Panasonic EverLEDs bulb, the Sharp 600 Series LED bulb (DL-L60AL), and the NEC LifeLED's bulb, that imitate the A-19/A-55 shape but are usually not exactly within the same form factor as incandescent light bulbs. Sometimes these LED bulbs are referred to as an “LED A-Style lamp.”

The LED bulb 40 has a bulb body 43 that is attached to a base 42. The base 42 can be a screw-type base used with Edison sockets or any other type of bulb base size or standard that is now or in the future used to insert light bulbs into light sockets and/or electrically connect light bulbs to mains power. The bulb body 43 and the base 42 are hollow and define a cavity 46 that is needed to house electronics 47 that drive the LEDs 44.

As shown, the shape of the bulb body 43 is approximately conical (with a round cross-section that increases away from the base 42), but a shape even more closely resembling A-bulbs can be used. A bulb cover 48 is attached to the bulb body 43. In one embodiment, the bulb cover 48 is the approximate shape of a half-sphere. The bulb cover 48 can be made or glass, plastic, or other materials, and is transparent or translucent to allow the light emitted by the LEDs 44 to illuminate the environment outside of the bulb body 43. In FIG. 3, the bulb cover 48 defines a bulb cavity, approximately defined as the area inside the truncated sphere of the bulb cover 48.

The LEDs 44 in the bulb cavity are mounted on a heat spreader 45 that is approximately disk-like in shape. The heat spreader conducts heat generated by the LEDs 44 to the bulb body 43, which acts as a heat sink and exchanges heat with the ambient air outside the bulb body 43 though convection. The bulb bodies 34 of some LED bulbs—such as bulb 40 shown in FIG. 3—have fins on the bulb body to increase surface area for heat exchange.

The LED light bulb 40 shown in and described with reference to FIG. 3 only uses passive cooling (a heat spreader and the bulb body) to thermally manage the LEDs. Passive cooling has limits on how much heat can be removed, thus limiting the number and brightness of the LEDs that can be used to generate light. One embodiment of the present invention adds active cooling to an LED bulb by placing an ion wind fan inside the LED bulb to enhance thermal management.

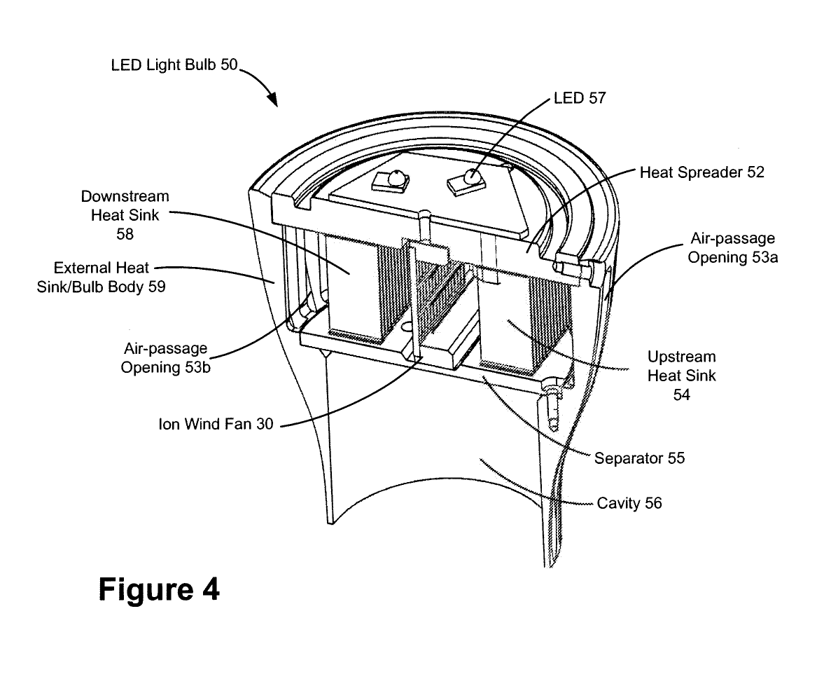

One such embodiment is now described with reference to FIG. 4. FIG. 4 illustrates an LED light bulb 50. The base and the bulb cover, as well as the drive electronics have been omitted from FIG. 4 for simplicity of illustration and ease of understanding. The external shape of the LED bulb 50 can be similar to the shape of bulb 40 in FIG. 3.

The LEDs 57 of the light bulb 50 are also mounted on the upper surface of a heat spreader 52, the upper surface being the surface inside the bulb cavity. There are two internal heat sinks thermally coupled to the lower surface of the heat spreader 52, designated in FIG. 4 as the upstream heat sink 54 and the downstream heat sink 58. In the illustrated embodiment, these internal heat sinks are fin stacks, but other heat sink geometries can be used.

In one embodiment, an ion wind fan 30 is positioned between the upstream 54 and downstream 58 heat sinks. The ion wind fan 30 can be supported by the heat spreader 52, a separator 55 physically separating the ion wind fan from the electronics cavity 56, or both. The upstream heat sink 54 and the downstream heat sink 58 can also be attached to the separator 55, which can act as a secondary heat spreader conducting heat to the bulb body 59.

The bulb body 59 has a number of air passage openings (e.g., 53a, 53b). In one embodiment, these openings are located so they allow ambient air to enter and exit the bulb body 59 between the heat spreader 52 and the separator 55. In other embodiments, they can extend beyond the separator 55, or to some other length in embodiments where no separator 55 is used.

The ion wind fan 30 is operable to generate and airflow. As shown in FIG. 4, the ion wind fan 30 will generate and airflow substantially parallel with the channels formed by the fins of the internal heat sinks Thus, ambient air will be pulled into the bulb from the side of the upstream heat sink 54 via air passage openings such as opening 53a.

The airflow will impinge on the surfaces of the upstream heat sink 54. This will heat the airflow, which also helps reduce the ozone generated by the ion wind fan 30. The airflow is accelerated through the ion wind fan 30 where it impinges on the surfaces of the downstream heat sink 58. The airflow then exits the bulb 50 through the air passage openings on the downstream side of the bulb body 59, such as opening 53b.

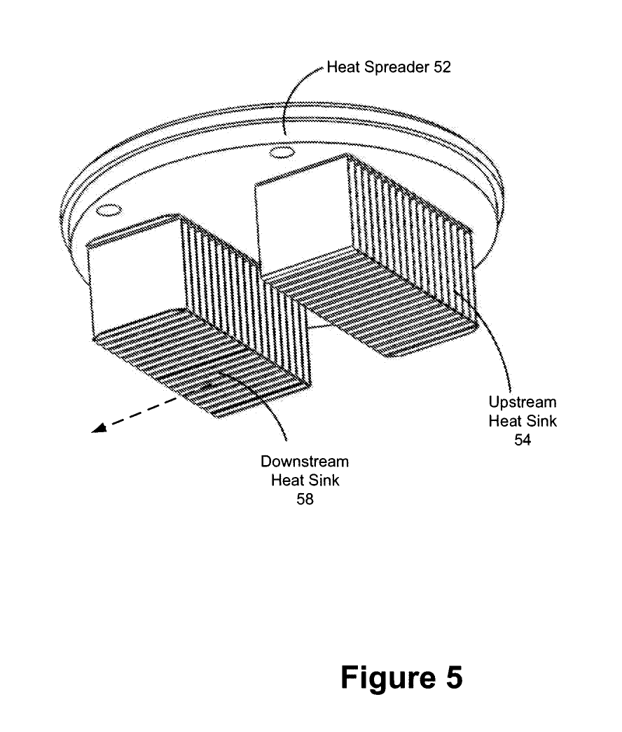

In one embodiment, the upstream heat sink 54 and the downstream heat sink 58 are identical, but in other embodiments they could be of different sizes, shapes, materials, and types and dimensions. For additional clarity, FIG. 5 illustrates the upstream heat sink 54 and the downstream heat sink 58 mounted on the bottom side of the heat spreader 52, with the dotted arrow representing the direction of the airflow generated by the ion wind fan 30.

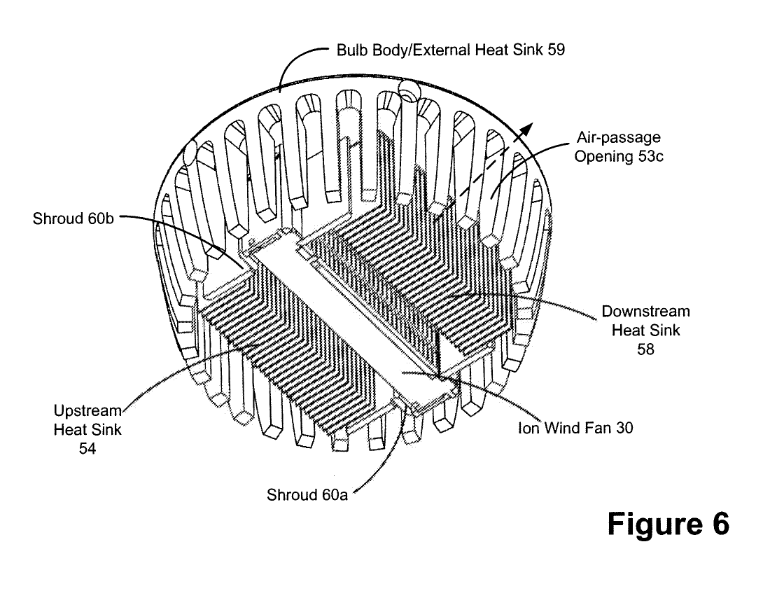

FIG. 6 is another perspective view of the bottom of the heat spreader 52 that includes—in addition to the upstream heat sink 54 and the downstream heat sink 58—the ion wind fan 30 oriented so that the collector electrode faces the viewer and portions of the bulb body 59 having air-passage openings 53, such as opening 53c. The dotted arrow again represents the approximate direction of the airflow generated by the ion wind fan 30.

In one embodiment, the LED light bulb 50 also includes air-guiding shrouds 60 to guide the airflow generated by the ion wind fan 30 between the heat sinks (54, 58) and the ion wind fan 30. For example, in FIG. 6, shroud 60a guides the airflow around the distal end of the ion wind fan 30 while shroud 60b guides the airflow around the proximal end of the ion wind fan 30. The shrouds 60 can function to prevent recirculation in the ion wind fan 30 and to ensure that all of the generated airflow impinges on the surfaces of both the upstream heat sink 54 and the downstream heat sink 58. In other embodiments, the shrouds 60 can be eliminated and the bulb body 59 can be formed in a way that performs the functionality of the shrouds 60.

In the embodiments described with reference to FIGS. 4-6, the upstream and downstream heat sinks are shown and described as fin-stack type heat sinks. The fins of fin-stack type heat sinks are generally parallel to each other, thus creating a straight air-passage channel. This design is advantageous, as it generated the least resistance to airflow, thus improving the ability of the heat sink to dissipate heat using convection, especially in forced convection applications.

While constructing prototype LED light bulbs, the inventors made the observation, that—while unlikely—it is possible for a person to reach into the bulb body 59 through some of the air passage openings 53 with a narrow pin-like metallic object and potentially touch the high-voltage emitter wires of the ion wind fan 30. This can be seen for example in FIG. 4, if a child poked into an operational LED bulb 50 with a needle through air-passage opening 53a. While such an event is extremely unlikely, and the shock received from the emitter wires would not be dangerous to humans because of the low power levels used by the ion wind fan 30, the inventors of the present applications developed several embodiments of the present invention that address this particular concern.

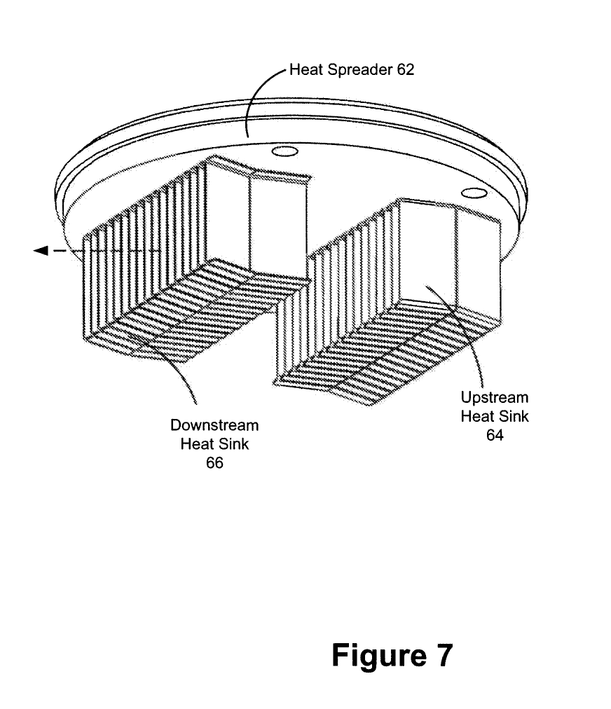

One such embodiment is now described with reference to FIG. 7. FIG. 7 is a perspective view of the bottom of a heat spreader 62 (which may be similar or identical to heat spreader 52 of FIG. 5). An upstream heat sink 64 and a downstream heat sink 66 are thermally coupled to the bottom surface of the heat spreader 62. However, the upstream heat sink 64 as well as the downstream heat sink 66 are no longer fin-stacks with straight rectangular fins, as in FIG. 5. Instead, in FIG. 7, the upstream heat sink 64 has angled fins (e.g., fin 65) stacked to create an angled-fin heat sink 64.

In one embodiment, each angled fin is has two rectangular portions that are at an angle from each other. The two portions can be made from one piece of metal (or other heat sink material) that is bent during manufacture. In other embodiment, the two portions can be joined during manufacture.

In one embodiment, the angle between the two portions of the fins (which can be referred to as the upstream and downstream portions based on their relation to the airflow), in addition to the fin spacing and fin length is selected so that the heat sink 64 blocks a direct line of sight from the upstream side of the heat sink 64 to the downstream side of the heat sink 64. In this manner, a pin-like object cannot be inserted from an air-passage opening to the emitter electrodes of the ion wind fan 30, since the pin-like object can no longer reach in a straight line through the upstream heat sink 64.

The downstream heat sink 66 faces the collector electrode of the ion wind fan 30 and not the high voltage emitter electrodes. While the collector electrode is grounded in some applications, in others it may also be a high or low voltage electrode.

Even if grounded, the collector electrode also has air passage openings through which small pin-like objects could theoretically pass. Thus, in one embodiment, the downstream heat sink 66 is also angled—as shown in FIG. 7—to eliminate a line of sight from the outside of the LED bulb to the ion wind fan 30.

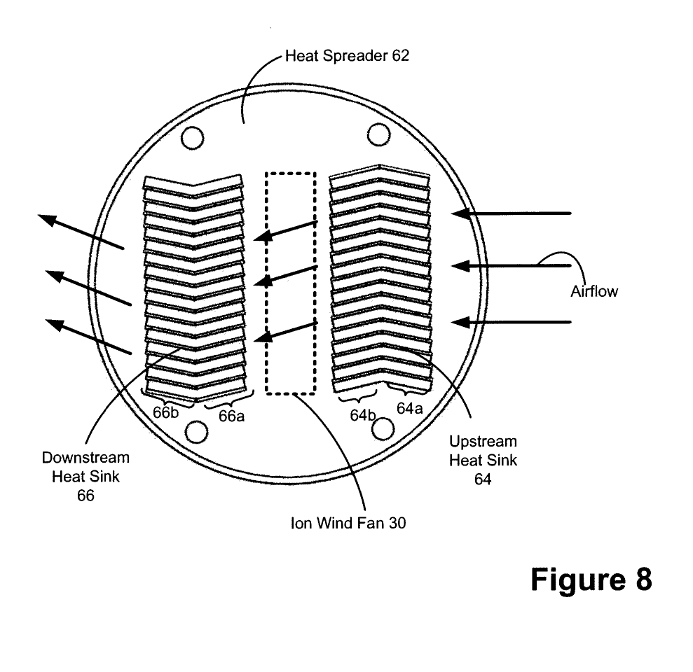

FIG. 8 is a bottom-up look at the heat spreader 62 from the base of the LED light bulb. This view provides a clear view of the angled fins forming the angled channels of the upstream heat sink 64 and the downstream heat sink 66. Arrows representing the airflow generated by the ion wind fan 30 are also provided for clarity and ease of understanding. These arrows are merely a representation, and do not aim to describe with accuracy the precise fluid flow.

As shown in FIG. 8, the air enters the bulb body and is directed leftward by the angle of the upstream portion 64a of the upstream heat sink 64. After passing the bend in the heat sink channel, the airflow is directed rightward by the downstream portion 64b of the upstream heat sink 64. The airflow is than accelerated through the ion wind fan 30 and enters the upstream portion 66a of the downstream heat sink 66 and continues rightward until the bend in the heat sink channel is reached. Then the airflow is again directed leftward by the downstream portion 66b of the downstream heat sink 66.

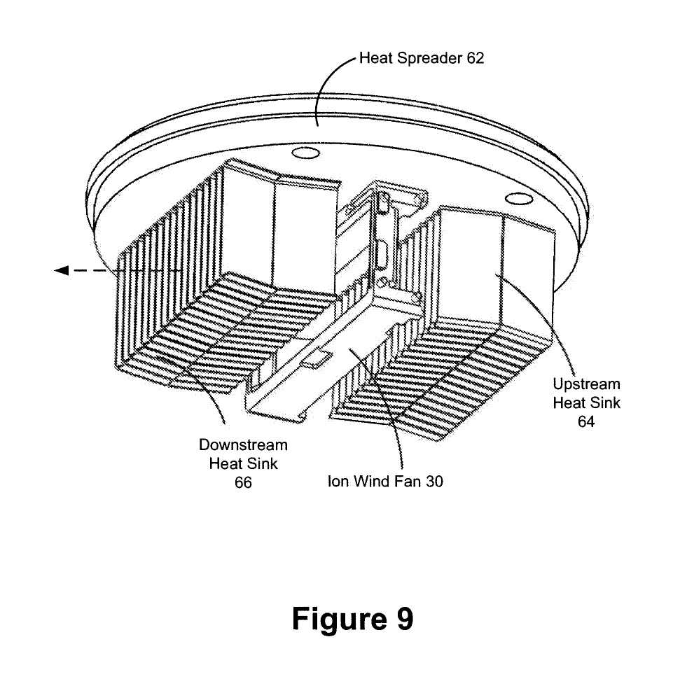

In FIG. 8 (and also FIGS. 9-11), the upstream and downstream portions of both the upstream 64 and downstream 66 heat sinks are shown and described as being of equal length. In other words, the air channels of the heat sinks have the same length before and after the bend. However, in other embodiments, either the portion upstream of the bend or the portion downstream of the bend can be longer than the other portion in either or both heat sinks.

FIG. 9 provides another perspective view of the bottom of the heat spreader 62. FIG. 9 is similar to FIG. 7, with the addition of the ion wind fan 30 and a dotted line representing the approximate direction of airflow.

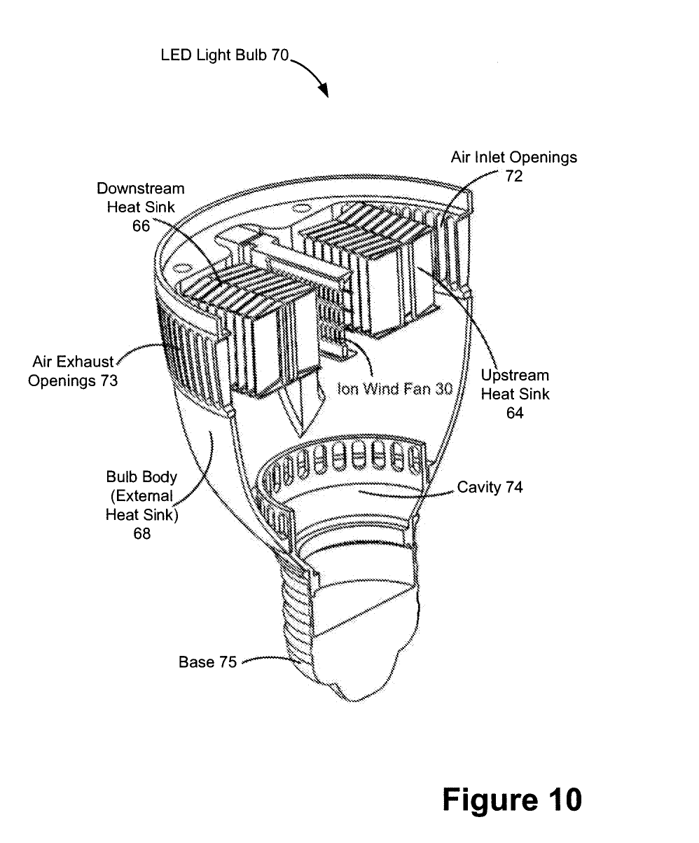

FIG. 10 shown one embodiment of an LED light bulb 70 having the angled bent-fin type heat sinks described with reference to FIGS. 7-9. FIG. 10 is a cross-sectional perspective view with the cross-section of the LED bulb 70 taken length wise parallel to the longitudinal axis extending from the center of the base 75 to the center of the bulb cover (not shown).

In many ways, the LED light bulb 70 is similar to the LED light bulb 50 discussed with reference to FIG. 4. One major difference is that the LED light bulb 70 has both an angled upstream heat sink 64 and an angled downstream heat sink 66. As can be seen from FIG. 10, the angled fins of the upstream heat sin 64 block a direct line of sight from any of the air inlet openings 72 to the ion wind fan 30. Similarly, the angled fins of the downstream heat sink 66 block a direct line of sight from any of the air exhaust openings 73 to the ion wind fan 30.

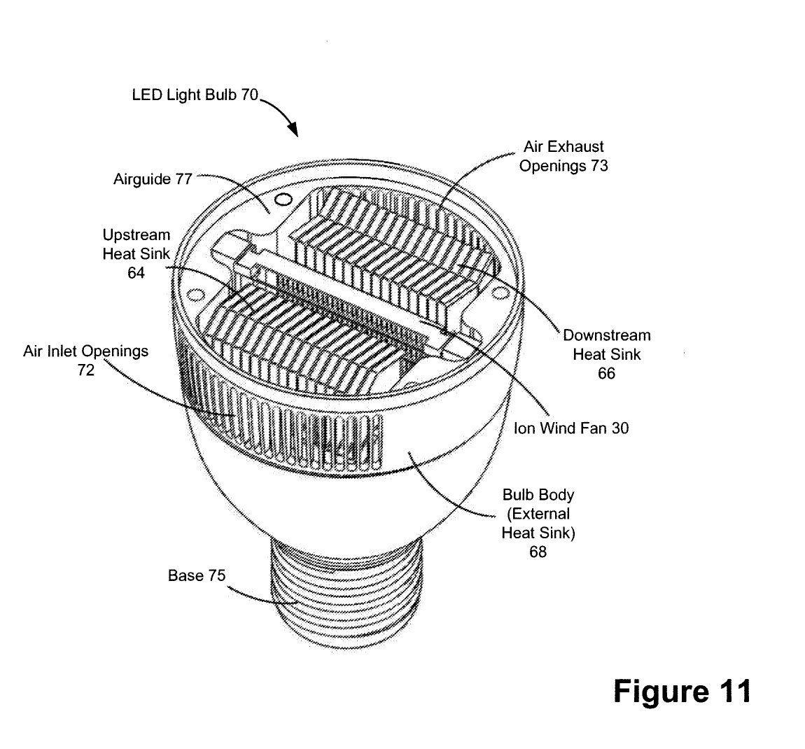

FIG. 11 is another cross-sectional perspective view of the LED bulb 70, this time the cross section taken in the plane of the heat spreader 62, which is not shown to expose the components underneath the heat spreader 62. Similarly, the bulb cover, LEDs, and bulb cavity are also not shown in FIGS. 10 and 11 for simplicity and ease of understanding. In FIG. 11 yet again shown the orientations of the angled fins of the upstream heat sink 64 and the downstream heat sink 66 in a way that prevents the insertion of pin-like objects into the ion wind fan 30.

In addition, another design feature of the embodiment of the present invention shown in FIG. 11 (and FIG. 10) is the separation of air inlet openings 72 and air exhaust openings 73. In the embodiment shown in FIG. 11, the portions of the sides of the LED light bulb 70 that are substantially perpendicular to the air flow generated by the ion wind fan 30 have no air passage openings. Furthermore, an internal air guide 77 that is part of the bulb body 68 guides the airflow from the air inlet openings 72 through the upstream heat sink 64 and then to the ion wind fan 30, from the ion wind fan 30 to the downstream heat sink 66, and finally out the air exhaust openings 73. Thus, in this embodiment, the internal air guide 77 is performing the functionality of the shroud 60 discussed with reference to FIG. 6.

In the embodiments shown in FIGS. 7-11, the upstream and downstream heat sinks are oriented in opposite directions. For example, in FIG. 11, the point of the bend that defines the “V” in the shape of the V-shaped fins of the upstream heat sink 64 points to the left side of the ion wind fan 30, whereas the V of the downstream heat sink 66 points to the right side of the ion wind fan 30.

This opposing orientation design has the advantage of letting the airflow take a substantially straight path between the bend in the upstream heat sink and the bend in the downstream heat sink. This can be seen, for example, in FIG. 8. However, in other embodiments, the upstream and downstream heat sinks may be oriented in the same direction.

While one advantage of the bent heat sink design shown in FIG. 7-11 is to protect the components of the LED bulb from tampering and to protect people from the high voltage emitter electrodes, the design has several other advantages. Ion wind fans occasionally spark across the air gap. Since the upstream and downstream heat sinks block any straight line of sight from the air passage openings on the bulb body to the ion wind fan, such sparks will now not be visible. Furthermore, it is aesthetically more pleasing for some people to not see the heat sinks and ion wind fan that is proverbially “under the hood” of the LED lamp.

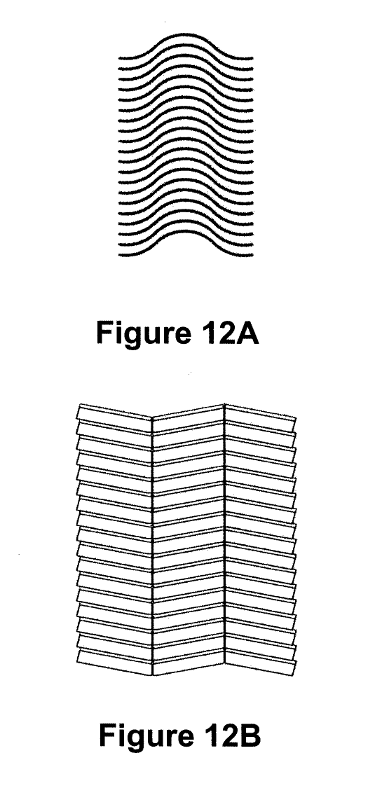

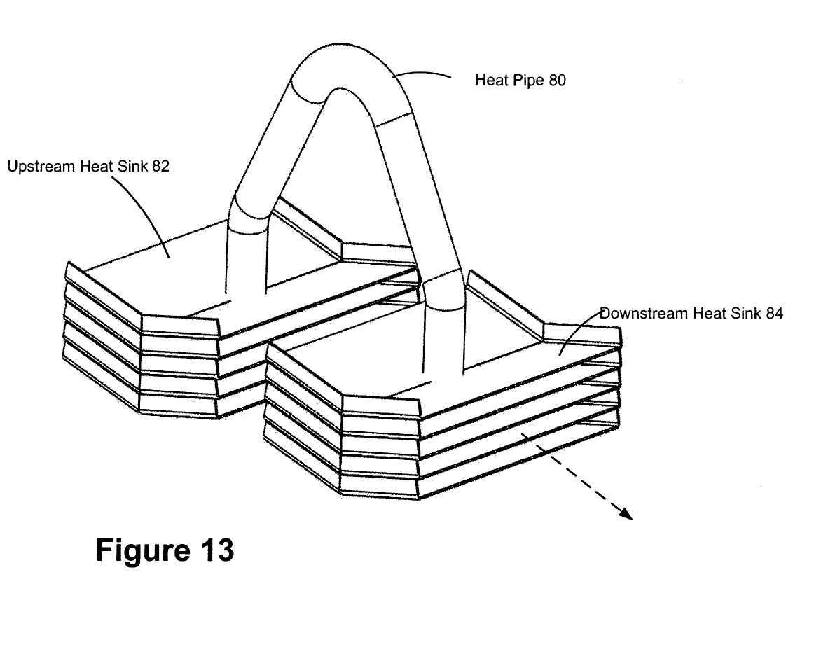

The upstream and downstream heat sinks are shown in FIGS. 7-11 as heat sinks having V-shaped fins. However other designs can be used. For example, the bend in the upstream and downstream heat sinks need not be a sharp angled bend, as in FIGS. 7-11. The bend can instead be a smooth rounded curve bend. Other types of curved bends can be used as well, such as the fin-pattern shown in FIG. 12A. FIG. 12A is a top view of a curved fm heat sink. The curves in the heat sink channels eliminate the line of sight through the heat sink much like the bent heat sink fins shown in FIGS. 7-11.

FIG. 12B further illustrates that the upstream and downstream heat sinks can have more than one bend in them. The heat sink in FIG. 12B, for example, has one bend to the left and one bend to the right.

Furthermore, in the description of FIGS. 7-11, as well as FIGS. 4-6, both the upstream and downstream heat sink has the same size and general shape. However this is not so in other embodiments. For example, in one embodiment, the upstream heat sink can be a single angle V-shaped heat sink (such as those in FIG. 7) while the downstream heat sink may be a single ripple-type heat sink (such as the geometry shown in FIG. 12A). The sizes of the upstream and downstream heat sinks and the length of their air channels can also vary. Furthermore, in some embodiments one heat sink is used, and one of the upstream or downstream heat sinks may be omitted.

The concept of creating a compact heat sink for an LED light bulb that protects the internal components by eliminating a direct line of sight from the outside of the LED light bulb to an ion wind fan inside the LED bulb can be implemented in a number of ways. The specific implementation shown in and described with reference to FIGS. 7-11 is merely one design implementation of the many possible embodiments of the present invention. For example, FIG. 13 illustrates how such a concept can be applied to an LED bulb having a heat pipe. This embodiment illustrates how the various embodiments of the present invention can be adapted to a wide variety of applications.

U.S. patent application Ser. No. 12/782,602 entitled “Solid-State Light Bulb Having an Ion Wind Fan and a Heat Pipe,” which is assigned to the assignee of the this Application and which is herein incorporated fully by reference, described an LED light bulb having a U-shaped heat pipe with two heat sinks attached to it and ion wind fan located between the two heat sinks. FIG. 13 shown such a heat pipe 80 having an upstream heat sink 82 thermally coupled to one parallel portion of the heat pipe 80 and a downstream heat sink 84 thermally coupled to the other parallel portion of the heat pipe 80. The dotted arrow shows the direction of the airflow generated by the ion wind fan (which is not shown for simplicity and ease of understanding).

As can be seen from FIG. 13, the upstream heat sink 82 and downstream heat sink 84 have bent V-shaped fins, much like the heat sinks shown in FIGS. 7-11. However, in FIG. 13, the point of the V-points downwards along the longitudinal axis of the LED bulb (and the parallel portions of the heat pipe 80), as opposed to left/right. In FIG. 13, both heat sinks point downward, but in other embodiments, one or both of them can be pointed upwards. The upstream and downstream heat sinks shown in FIG. 13 also block a direct line of sight to the ion wind fan that will be positioned between the upstream and downstream heat sinks.

In the descriptions above, various functional modules are given descriptive names, such as “ion wind fan power supply.” The functionality of these modules can be implemented in software, firmware, hardware, or a combination of the above. None of the specific modules or terms—including “power supply” or “ion wind fan”—imply or describe a physical enclosure or separation of the module or component from other system components.

Furthermore, descriptive names such as “emitter electrode,” “collector electrode,” and “isolator,” are merely descriptive and can be implemented in a variety of ways. For example, the “collector electrode,” can be a plate-like component with oval air-passage openings (as shown in the Figures), but it can also be made of multiple rods spaced apart, a mesh screen, or in numerous other geometries. The embodiments of the present invention are not limited to any particular kind of collector electrode.

Similarly, the isolator can be the substantially frame-like component shown in the Figures, but it can have various shapes. The electrodes and the isolator are not limited to any particular material; however, the isolator will generally be made of a dielectric material.

As mentioned above, various embodiments of the present invention are applicable to any form of solid-state lighting, even though the embodiments are described in terms of LED lighting for simplicity and ease of understanding. Furthermore, the present invention is not limited to any specific ion wind technology or ion wind fan shape or size. Also, while some embodiments of the present invention are specific to solid-state light devices, other embodiments can be implemented in and used as thermal management of any electronics device—such as TVs, portable devices, storage devices, computers, ect.—even if only shown described in the context of LED lighting in the description above.

What is claimed:

1. A lighting device comprising:
a bulb body;
a bulb cover attached to the bulb body;
a heat spreader attached to the bulb body, where the bulb cover and the heat spreader define a bulb cavity;
one or more solid-state light devices attached to a first surface of the heat spreader, the first surface of the heat spreader being inside the bulb cavity;
a first heat sink thermally coupled to a second surface of the heat spreader, the second surface of the heat spreader being outside of the bulb cavity;
a second heat sink thermally coupled to the second surface of the heat spreader; and
an ion wind fan disposed to generate an airflow that impinges on the first heat sink and the second heat sink.

2. The lighting device of claim 1, wherein the ion wind fan is located between the first heat sink and the second heat.

3. The lighting device of claim 1, further comprising a base attached to the bulb body, the base configured to electrically connect the lighting device to a power source, wherein the a base in combination with the bulb body and the bulb cover have the approximate shape of A-style bulb.

4. The lighting device of claim 1, wherein the bulb body comprises a plurality of air passage openings.

5. The lighting device of claim 1, wherein the lighting device has a longitudinal axis extending form the center of the base to the center of the bulb cover, and the airflow generated by the ion wind fan is perpendicular to the longitudinal axis of the lighting device.

6. The lighting device of claim 1, wherein the first heat sink and the second heat sink comprise fin-stack type heat sinks.

7. The lighting device of claim 6, wherein the first heat sink and the second heat sink comprise a plurality of V-shaped fins.

8. The lighting device of claim 6, wherein the first heat sink and the second heat sink are oriented in opposite directions with respect to each other.

9. The lighting device of claim 6, wherein the first heat sink and the second heat sink comprise a plurality of bent fins.

10. The lighting device of claim 1, wherein the one or more solid-state light devices comprise light-emitting diodes (LEDs).

11. A lighting device comprising:
a bulb body having one or more air intake openings and a one or more air exhaust openings;
an ion wind fan capable of generating an airflow from the air intake openings toward the air exhaust opening, the ion wind fan being located inside the bulb body; and
an upstream heat sink disposed upstream of the ion wind fan with respect to the airflow, the upstream heat sink having a shape that provides no direct line of sight from the air intake openings to the ion wind fan.

12. The lighting device of claim 11, further comprising a downstream heat sink disposed downstream of the ion wind fan with respect to the airflow, the downstream heat sink having a shape that provides no direct line of sight from the air exhaust openings to the ion wind fan.

13. The lighting device of claim 12, wherein the upstream and downstream heat sinks comprise V-shaped fin stacks.

14. The lighting device of claim 13, wherein the V-shapes of the upstream and downstream heat sinks are oriented in opposing directions.

15. The lighting device of claim 11, wherein the one or more solid-state light devices comprise light-emitting diodes (LEDs).

16. A consumer electronics device comprising:
a body having one or more air passage openings to allow ambient air into the body of the consumer electronics device;
an ion wind fan to create an air flow through the one or more air passage openings; and
a heat sink located between the one or more air passage openings and the ion wind fan, the heat sink having a shape that prevents at least one object that fits through the one or more air passage openings from being able to contact the ion wind fan.

17. The consumer electronics device of claim 16, wherein the heat sink comprises a plurality of heat sink fins, each heat sink fin being bent to form non-straight air passage channels.

18. The consumer electronics device of claim 17, wherein each heat sink fin is bent at an angle to form substantially V-shaped air passage channels.

19. The consumer electronics device of claim 17, wherein each heat sink fin is bent in a curve to form curved air passage channels.

20. A consumer electronics device comprising:
an ion wind fan to generate an airflow;
a first heat sink positioned upstream of the ion wind fan with respect to the airflow, wherein the airflow is heated by impinging on the first heat sink; and
a second heat sink positioned downstream of the ion wind fan with respect to the airflow, wherein the heated airflow impinges on the second heat sink.

21. The consumer electronics device of claim 20, wherein the ion wind fan generates less ozone due to the heated air received from the first heat sink.

22. The consumer electronics device of claim 20, further comprising an external shell having one or more air intake openings, wherein the first heat sink is shaped in a manner that protects the ion wind fan from objects inserted through an air intake opening.
